(19) United States
(12) Patent Application Publication
(10) Pub. No.: US 2024/0321612 A1
(43) Pub. Date: Sep. 26, 2024

(54) SUBSTRATE PROCESSING APPARATUS, SUBSTRATE CHECKING METHOD, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventors: Takuya SAITO, Toyama (JP); Taiyo OKAZAKI, Toyama (JP); Shin HIYAMA, Toyama (JP); Shin TSUJIMURA, Toyama (JP)

(21) Appl. No.: 18/601,076

(22) Filed: Mar. 11, 2024

(30) Foreign Application Priority Data
Mar. 24, 2023 (JP) 2023-049051

(51) Int. Cl. H01L 21/67; B65G 47/90; H01L 21/673

(52) U.S. Cl. CPC H01L 21/67288; B65G 47/905; H01L 21/67201; H01L 21/67259; H01L 21/67303

(57) ABSTRACT

A technique capable of performing an abnormality determination on each substrate transferred to a load lock chamber with less dependence a structure of the load lock chamber is described. A substrate processing apparatus includes: a substrate support provided in the load lock chamber and capable of supporting a plurality of substrates in a multistage manner at predetermined intervals; an elevator capable of elevating and lowering the substrate support; a plurality of sensors respectively provided on outer peripheral portions of the upper region and the lower region in the load lock chamber and configured to check a state of the substrate supported by the substrate support; and a controller including an abnormality determinator and configured to be capable of controlling the abnormality determinator configured to perform an abnormality determination on the substrate based on data respectively sent from the plurality of sensors and a predetermined threshold value.

### CROSS REFERENCE TO RELATED APPLICATIONS

This non-provisional U.S. patent application is based on and claims priority under 35 U.S.C. § 119 to Japanese Patent Application No. 2023-049051, filed on Mar. 24, 2023, in the Japanese Patent Office, the entire contents of which are hereby incorporated by reference.

### TECHNICAL FIELD

The present disclosure relates to a substrate processing apparatus, a substrate checking method, a method of manufacturing a semiconductor device and a non-transitory computer-readable recording medium.

### BACKGROUND

Conventionally, a substrate processing apparatus provided with a load lock chamber may be used. A substrate may be transferred (loaded) into the load lock chamber or transferred (unloaded) from the load lock chamber. According to some related arts, the load lock chamber of the substrate processing apparatus is provided with a function of switching an inner atmosphere of the load lock chamber between an atmospheric state and a vacuum state.

When determining a presence or absence of each substrate transferred to the load lock chamber, for example, a support (that is, a substrate support) configured to support the substrates in a multistage manner with a predetermined interval therebetween may be elevated and lowered in the load lock chamber to sequentially check slots of the substrate support from a lowermost slot to an uppermost slot using a component such as a sensor. However, in order to check the slots from the lowermost slot to the uppermost slot of the substrate support using a single sensor, a structure of the load lock chamber may be changed. For example, a height of the load lock chamber is increased to provide a sufficient space for the substrate support to move up and down.

### SUMMARY

According to the present disclosure, there is provided a technique capable of performing an abnormality determination on each substrate transferred to a load lock chamber with less dependence to a structure of the load lock chamber.

According to embodiments of the present disclosure, there is provided a technique that includes: a load lock chamber comprising: an opening through which a substrate among a plurality of substrates is capable of being loaded into or unloaded from the load lock chamber; and an upper region and a lower region with the opening interposed therebetween; a substrate support provided in the load lock chamber and capable of supporting the plurality of substrates in a multistage manner at predetermined intervals; an elevator capable of elevating and lowering the substrate support; a plurality of sensors respectively provided on outer peripheral portions of the upper region and the lower region in the load lock chamber and configured to check a state of the substrate supported by the substrate support; and a controller comprising an abnormality determinator and configured to be capable of controlling the abnormality determinator configured to perform an abnormality determination on the substrate based on data respectively sent from the plurality of sensors and a predetermined threshold value.

### BRIEF DESCRIPTION OF THE DRAWINGS

FIG. 1 is a diagram schematically illustrating a configuration of a substrate processing apparatus according to one or more embodiments of the present disclosure.

FIG. 2 is a diagram schematically illustrating a vertical cross-section of the substrate processing apparatus according to the embodiments of the present disclosure.

FIG. 3 is a diagram schematically illustrating a vertical cross-section of a load lock chamber of the substrate processing apparatus according to the embodiments of the present disclosure.

FIG. 4A is a diagram schematically illustrating a vertical cross-section of the load lock chamber of the substrate processing apparatus according to the embodiments of the present disclosure in a state where an elevation position of a boat is moved to a first elevation position.

FIG. 4B is a diagram schematically illustrating a vertical cross-section of the load lock chamber of the substrate processing apparatus in a state where the elevation position of the boat is moved from the first elevation position shown in FIG. 4A to a second elevation position.

FIG. 4C is a diagram schematically illustrating a vertical cross-section of the load lock chamber of the substrate processing apparatus in a state where the elevation position of the boat is moved from a third elevation position shown in FIG. 4B to a fourth elevation position.

FIG. 5 is a block diagram schematically illustrating a configuration of a controller and related components of the substrate processing apparatus according to the embodiments of the present disclosure.

FIG. 6A is a diagram schematically illustrating a state where the boat supports a plurality of substrates, which is obtained by each sensor used in the substrate processing apparatus according to the embodiments of the present disclosure.

FIG. 6B is a diagram schematically illustrating an enlarged view of a part of FIG. 6A.

FIG. 7 is a diagram for explaining waveform data obtained by a sensor.

FIG. 8A is a flow chart schematically illustrating a flow of an abnormality determination process for each substrate in the substrate processing apparatus according to the embodiments of the present disclosure.

FIG. 8B is a flow chart schematically illustrating a flow of an abnormality determination process for each substrate in the substrate processing apparatus according to the embodiments of the present disclosure.

### DETAILED DESCRIPTION

### Embodiments of Present Disclosure

Hereinafter, one or more embodiments (also simply referred to as “embodiments”) according to the technique of the present disclosure will be described with reference to the drawings. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

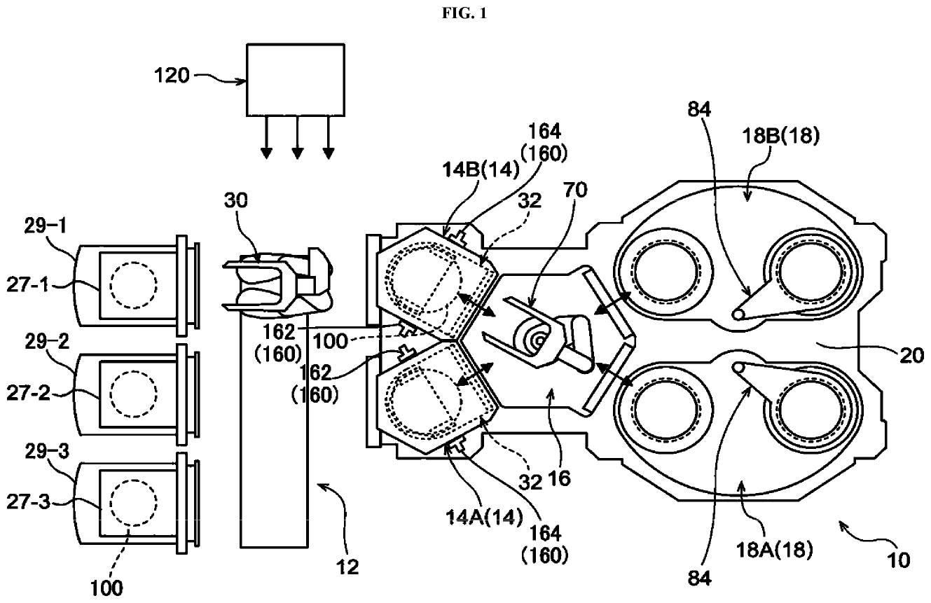

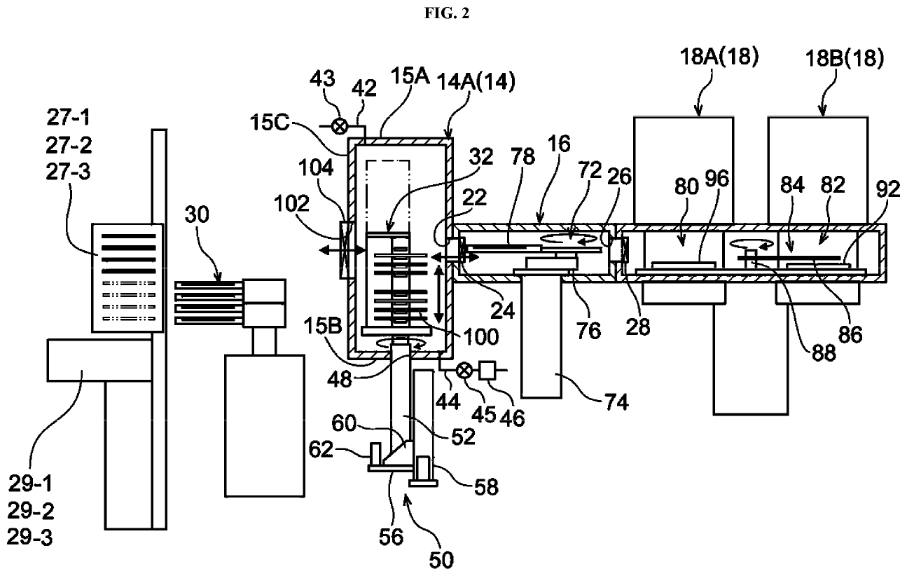

As shown in FIGS. 1 and 2, a substrate processing apparatus 10 according to the present embodiments may include: an atmospheric transfer chamber (EFEM: Equipment Front End Module) 12; loading port structures 29-1, 29-2 and 29-3 connected to the atmospheric transfer chamber 12 and serving as mounting structures (placing structures) on which pods 27-1, 27-2 and 27-3 serving as substrate storage containers are placed; load lock chambers 14A and 14B serving as pressure-controlled preliminary chambers; a transfer chamber 16 serving as a vacuum transfer chamber; and process chambers 18A and 18B in which a plurality of substrates 100 are processed. Hereinafter, each of the plurality of substrates 100 may also be referred to as a “substrate 100”. Further, a partition wall (which is a boundary wall) 20 is provided so as to separate the process chamber 18A and the process chamber 18B. According to the present embodiments, a semiconductor wafer such as a silicon wafer on which a semiconductor device is manufactured may be used as the substrate 100.

According to the present embodiments, configurations of the load lock chambers 14A and 14B (including configurations associated with the load lock chambers 14A and 14B) are substantially the same. Therefore, the load lock chambers 14A and 14B may also be collectively or individually referred to as a “load lock chamber 14”.

Further, according to the present embodiments, configurations of the process chambers 18A and 18B (including configurations associated with the process chambers 18A and 18B) are substantially the same. Therefore, the process chambers 18A and 18B may also be collectively or individually referred to as a “process chamber 18”.

As shown in FIG. 2, a communication structure 22 is provided between the load lock chamber 14 and the transfer chamber 16 so as to communicate between adjacent chambers (that is, the load lock chamber 14 and the transfer chamber 16). The communication structure 22 is configured to be opened or closed by a gate valve 24.

As shown in FIG. 2, a communication structure 26 is provided between the transfer chamber 16 and the process chamber 18 so as to communicate between adjacent chambers (that is, the transfer chamber 16 and the process chamber 18). The communication structure 26 is configured to be opened or closed by a gate valve 28.

An atmospheric robot 30 serving as an atmospheric transfer structure is provided in the atmospheric transfer chamber 12. The atmospheric robot 30 is capable of transferring the substrate 100 between the load lock chamber 14 and each of the pods 27-1 to 27-3 placed on the loading port structures 29-1 to 29-3, respectively. The atmospheric robot 30 is configured to be capable of simultaneously transferring two or more substrates among the substrates 100 in the atmospheric transfer chamber 12.

The load lock chamber 14 is configured such that the substrate 100 is transferred (loaded) into or transferred (unloaded) out of the load lock chamber 14. Specifically, an unprocessed substrate among the substrates 100 is loaded into the load lock chamber 14 by the atmospheric robot 30. Hereinafter, the unprocessed substrate among the substrates 100 may also be simply referred to as an “unprocessed substrate 100”. The unprocessed substrate 100 loaded into the load lock chamber 14 is then unloaded out of the load lock chamber 14 by a vacuum robot 70 described later. On the other hand, a processed substrate among the substrates 100 is loaded into the load lock chamber 14 by the vacuum robot 70. Hereinafter, the processed substrate among the substrates 100 may also be simply referred to as a “processed substrate 100”. The processed substrate 100 loaded into the load lock chamber 14 is then unloaded out of the load lock chamber 14 by the atmospheric robot 30.

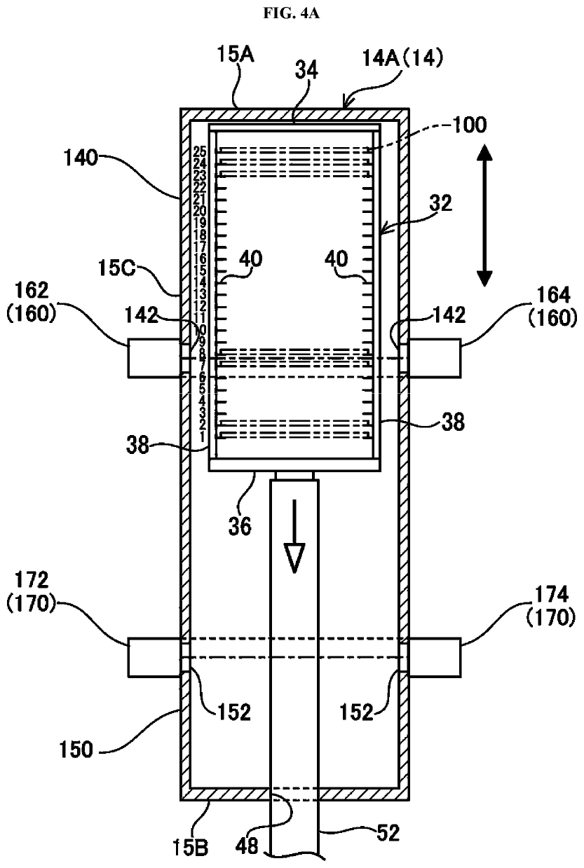

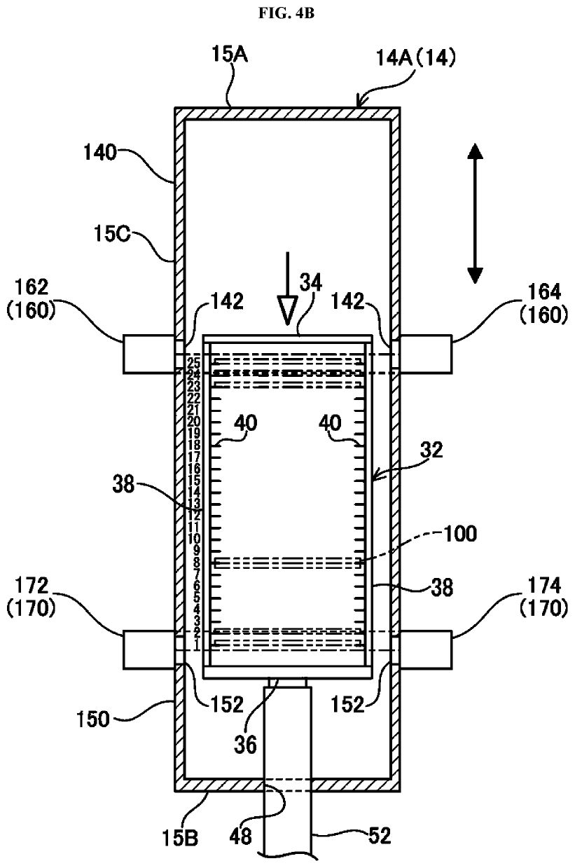

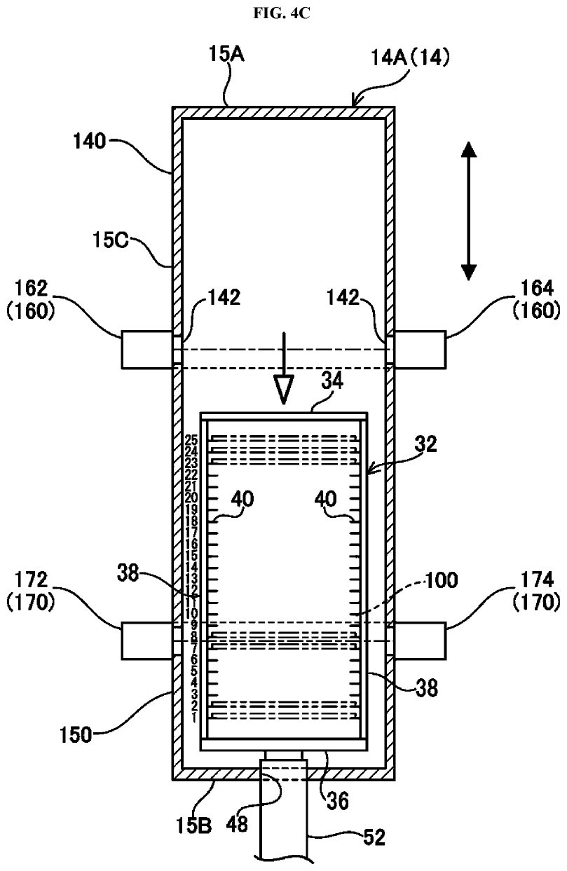

Further, a boat 32 serving as a substrate support capable of supporting the substrate 100 is provided in the load lock chamber 14. As shown in FIG. 4A, the boat 32 is provided so as to support at least one substrate 100 (for example, from 1 substrate to 25 substrates) in a multistage manner with a predetermined interval therebetween and so as to accommodate the at least one substrate 100 in a horizontal orientation. Specifically, the boat 32 may be embodied by a structure in which an upper plate 34 and a lower plate 36 are connected by a plurality of support columns 38. Further, in the present specification, a notation of a numerical range such as “from 1 substrate to 25 substrates” means that a lower limit and an upper limit are included in the numerical range. Therefore, for example, a numerical range “from 1 substrate to 25 substrates” means a range equal to or more than 1 substrate and equal to or less than 25 substrates. The same also applies to other numerical ranges described herein.

For example, a plurality of support structures (for example, from 1 support structure to 25 support structures) including a support structure 40 configured to support the substrate 100 are provided at the support columns 38. Hereinafter, the plurality of support structures including the support structure 40 may also be simply referred to as “support structures 40”. The support structures 40 are provided parallel to one another with a predetermined interval therebetween.

As shown in FIG. 2, a gas supply pipe 42 communicating with an inside of the load lock chamber 14 is connected to a top plate 15A constituting the load lock chamber 14. A gas supply source (not shown) capable of supplying an inert gas (for example, nitrogen gas or a rare gas) and a gas supply valve 43 are sequentially provided at the gas supply pipe 42 in this order from an upstream side toward a downstream side of the gas supply pipe 42 along a gas flow direction.

For example, a cooling structure (not shown) such as a coolant circulation channel is provided at the top plate 15A. The substrate 100 supported by the boat 32 can be cooled by the cooling structure. Specifically, the processed substrate 100 heated after being processed in the process chamber 18 is cooled by the cooling structure.

An exhaust pipe 44 communicating with the inside of the load lock chamber 14 is connected to a bottom plate 15B constituting the load lock chamber 14. A valve 45 and a vacuum pump 46 serving as a vacuum exhaust apparatus are sequentially provided at the exhaust pipe 44 in this order from an upstream side toward a downstream side of the exhaust pipe 44 along the gas flow direction.

According to the present embodiments, the gas supply valve 43 is closed while the communication structures 22 and 26 are closed by the gate valves 24 and 28, respectively. In such a state, when the valve 45 is opened and the vacuum pump 46 is operated, an inner atmosphere of the load lock chamber 14 is vacuum exhausted such that an inner pressure of the load lock chamber 14 can be set (adjusted) to a vacuum pressure (or a decompressed state). In addition, in a state in which the communication structures 22 and 26 are closed by the gate valves 24 and 28, respectively, when the valve 45 is closed (or an opening degree of the valve 45 is reduced) and the gas supply valve 43 is opened to supply the inert gas into the load lock chamber 14, the inner pressure of the load lock chamber 14 can be set to an atmospheric pressure.

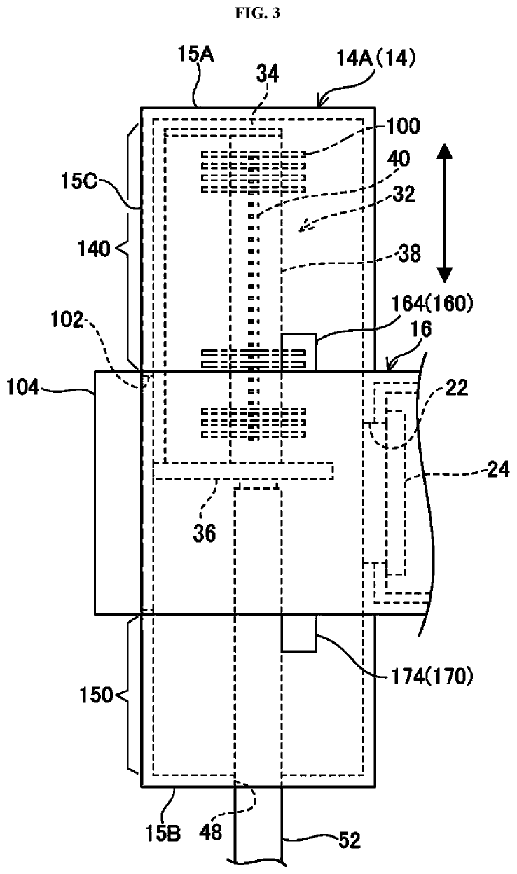

As shown in FIG. 3, an opening 102 is provided on an outer peripheral wall 15C constituting the load lock chamber 14. The substrate 100 can be loaded into or unloaded from the load lock chamber 14 through the opening 102. Specifically, the opening 102 is provided on the outer peripheral wall 15C so as to face the atmospheric robot 30. The atmospheric robot 30 is configured to transfer the substrate 100 to the boat 32 through the opening 102 such that the substrate 100 is supported by the boat 32 and to transfer (take out) the substrate 100 from the boat 32 through the opening 102.

For example, a gate valve 104 capable of opening and closing the opening 102 is provided on the outer peripheral wall 15C.

Further, the load lock chamber 14 includes an upper region 140 and a lower region 150 with the opening 102 therebetween. According to the present embodiments, a space above the opening 102 is referred to as the “upper region 140”, and a space below the opening 102 is referred to as the “lower region 150”.

For example, sensors 160 and 170 are provided on the outer peripheral wall 15C (that is, an outer peripheral portion) corresponding to the upper region 140 and the lower region 150 in the load lock chamber 14, respectively. That is, the sensor 160 is arranged in a portion of the outer peripheral wall 15C corresponding to the upper region 140, and the sensor 170 is arranged in a portion of the outer peripheral wall 15C corresponding to the lower region 150. According to the present embodiments, for example, each of the sensor 160 and the sensor 170 is fixed to the outer peripheral wall 15C.

The sensors 160 and 170 serve as sensors for checking a state of the substrate 100 supported by the boat 32. Specifically, each of the sensors 160 and 170 may be configured as a transmission type optical sensor. Further, in the sensor 160, a transmitter 162 and a receiver 164 are disposed at mutually opposing positions in a radial direction of the substrate 100 supported by the boat 32. In other words, the sensor 160 is a set of a light emitting sensor and a light receiving sensor. Similarly, in the sensor 170, a transmitter 172 and a receiver 174 are disposed at mutually opposing positions in the radial direction of the substrate 100 supported by the boat 32. In other words, the sensor 170 is a set of a light emitting sensor and a light receiving sensor. The sensor 160 of the present embodiments serves as an example of a first sensor of the present disclosure, and the sensor 170 of the present embodiments serves as an example of a second sensor of the present disclosure.

As shown in FIG. 4A, a portion of the outer peripheral wall 15C corresponding to an optical path of the sensor 160 is configured as a window (that is, a window structure) 142. For example, the window 142 is made of a material through which a light can pass. Similarly, a portion of the outer peripheral wall 15C corresponding to an optical path of the sensor 170 is configured as a window (that is, a window structure) 152. For example, the window 152 is made of a material through which the light can pass.

Data acquired by the sensors 160 and 170 is configured to be transmitted to a controller 120.

According to the present embodiments, for example, the sensors 160 and 170 are arranged so as to divide the boat 32 into an upper range corresponding to the upper region 140 and a lower range corresponding to the lower region 150, and to check the state of the substrate 100 supported by the boat 32.

As shown in FIGS. 2 and 3, an opening 48 communicating between the inside and outside of the load lock chamber 14 is provided at the bottom plate 15B of the load lock chamber 14. A driver (which is a driving structure) 50 capable of elevating and lowering the boat 32 and rotating the boat 32 through the opening 48 is provided below the load lock chamber 14.

The driver 50 may include: a shaft 52 serving as a support shaft capable of supporting the boat 32; a bellows (which is extendable and retractable, not shown) provided so as to surround the shaft 52; a fixing base 56 to which lower ends of the shaft 52 and the bellows are fixed; an elevation driver (which is an elevation driving structure or an elevator) 58 capable of elevating and lowering the boat 32 via the shaft 52; a connection structure 60 capable of connecting the elevation driver 58 and the fixing base 56; and a rotation driver (which is a rotation driving structure) 62 capable of rotating the boat 32.

The elevation driver 58 is configured to elevate or lower the boat 32 along a direction in which the substrates 100 are stacked in the multistage manner.

An upper end of the bellows is fixed around the opening 48 provided in the bottom plate 15B constituting the load lock chamber 14.

The rotation driver 62 is configured to rotate the boat 32 about an axis extending along the direction in which the substrates 100 are stacked in the multistage manner. Specifically, the rotation driver 62 rotates the boat 32 around the shaft 52 serving as a rotation axis.

The vacuum robot 70 serving as a vacuum transfer structure is provided in the transfer chamber 16. The vacuum robot 70 is configured to transfer the substrate 100 between the load lock chamber 14 and the process chamber 18. The vacuum robot 70 may include: a substrate transfer structure 72 capable of supporting and transferring the substrate 100; and a transfer driver (which is a transfer driving structure) 74 capable of rotating the substrate transfer structure 72 and elevating or lowering the substrate transfer structure 72.

An arm structure 76 is provided in the substrate transfer structure 72. The arm structure 76 is provided with a finger 78 on which the substrate 100 is placed. Alternatively, a plurality of fingers including the finger 78 may be provided on the arm structure 76 with a predetermined interval therebetween in the vertical direction. For example, a plurality of arm structures including the arm structure 76 may be provided in a multistage manner. In addition, the finger 78 is configured to be extendable and retractable in a substantially horizontal direction.

The substrate 100 can be moved from the load lock chamber 14 to the process chamber 18 by moving the substrate 100 supported by the boat 32 into the transfer chamber 16 by the vacuum robot 70 via the communication structure 22 and further moving the substrate 100 into the process chamber 18 by the vacuum robot 70 via the communication structure 26.

Further, the substrate 100 can be moved from the process chamber 18 to the load lock chamber 14 by moving the substrate 100 in the process chamber 18 into the transfer chamber 16 by the vacuum robot 70 via the communication structure 26 and then by supporting the substrate 100 on the boat 32 by the vacuum robot 70 via the communication structure 22.

A first process structure 80, a second process structure 82 located farther from the transfer chamber 16 than the first process structure 80 and a substrate mover (which is a substrate moving structure) 84 capable of transferring the substrate 100 between the second process structure 82 and the vacuum robot 70 are provided in the process chamber 18.

The first process structure 80 may include a first mounting table (which is a first placing table) 96 on which the substrate 100 is placed and a first heater (not shown) configured to heat the first mounting table 96.

The second process structure 82 may include a second mounting table (which is a second placing table) 92 on which the substrate 100 is placed and a second heater (not shown) configured to heat the second mounting table 92.

The first process structure 80 and the second process structure 82 are configured to process the substrate 100 likewise (that is, in the same manner).

The substrate mover 84 is constituted by a mover (which is a moving structure) 86 capable of supporting the substrate 100 and a moving shaft 88 provided in the vicinity of the partition wall 20. The mover 86 is provided so as to be rotatable around the moving shaft 88 serving as a rotation axis. Further, the mover 86 can be elevated and lowered around the moving shaft 88.

For example, by rotating the mover 86 toward the first process structure 80, the substrate mover 84 is capable of transferring the substrate 100 to or from the vacuum robot 70 at the first process structure 80. Thereby, the substrate mover 84 is capable of moving the substrate 100 transferred by the vacuum robot 70 to the second mounting table 92 of the second process structure 82 and also capable of moving the substrate 100 placed on the second mounting table 92 to the vacuum robot 70.

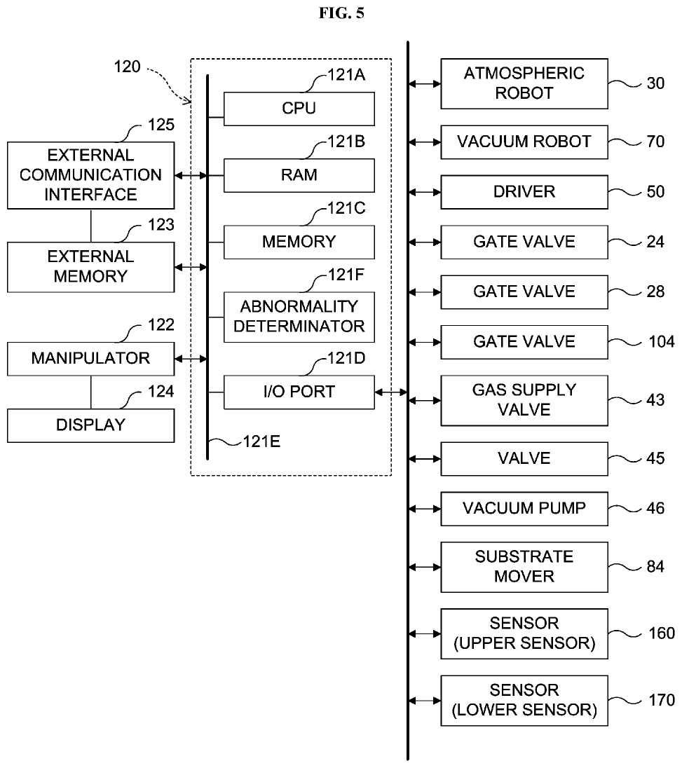

As shown in FIG. 1, the substrate processing apparatus 10 includes the controller 120 serving as a control structure. For example, as shown in FIG. 5, the controller 120 is constituted by a computer including a CPU (Central Processing Unit) 121A, a RAM (Random Access Memory) 121B, a memory 121C, an I/O port (input/output port) 121D and an abnormality determinator (which is an abnormality determination structure) 121F.

The RAM 121B, the memory 121C, the I/O port 121D and the abnormality determinator 121F may exchange data with the CPU 121A through an internal bus 121E. For example, a manipulator 122 may be connected to the controller 120. A display (which is a display structure) 124 is connected to the manipulator 122, and is configured to be capable of displaying the state of the substrate 100. For example, the manipulator 122 may be constituted by a component such as a touch panel. In such a case, the manipulator 122 and the display 124 may be provided in the same housing. Further, an external communication interface 125 for communicating with an external apparatus may be connected to the controller 120.

For example, the memory 121C is configured by a component such as a flash memory and a hard disk drive (HDD). For example, a control program configured to control operations of the substrate processing apparatus 10 and a process recipe containing information on sequences and conditions of a substrate processing described later may be readably stored in the memory 121C. The process recipe is obtained by combining steps of the substrate processing described later such that the controller 120 can execute the steps by using the substrate processing apparatus 10 to acquire a predetermined result, and functions as a program. Hereinafter, the process recipe and the control program may be collectively or individually referred to as a “program.” Further, the process recipe may also be simply referred to as a “recipe.” Thus, in the present specification, the term “program” may refer to the recipe alone, may refer to the control program alone, or may refer to both of the recipe and the control program. The RAM 121B functions as a memory area (work area) where a program or data read by the CPU 121A is temporarily stored.

The I/O port 121D is connected to components such as the atmospheric robot 30, the vacuum robot 70, the driver 50, the gate valve 24, the gate valve 28, the gate valve 104, the gas supply valve 43, the valve 45, the vacuum pump 46, the substrate mover 84, the sensor (upper sensor) 160, the sensor (lower sensor) 170, the first heater (not shown) and the second heater (not shown).

The CPU 121A is configured to read and execute the control program stored in the memory 121C, and to read the recipe stored in the memory 121C in accordance with an instruction such as an operation command inputted via the manipulator 122. For example, in accordance with contents of the read recipe, the CPU 121A is configured to be capable of controlling various operations such as a transfer operation for the substrate 100 by the atmospheric robot 30, the vacuum robot 70, the driver 50 and the substrate mover 84, opening and closing operations of the gate valve 24, the gate valve 28 and the gate valve 104, a flow rate adjusting operation and a pressure adjusting operation by the gas supply valve 43, the valve 45 and the vacuum pump 46 and a temperature adjusting operation by the first heater and the second heater.

The controller 120 may be embodied by installing the above-described program stored in an external memory 123 into the computer. For example, the external memory 123 may be constituted by a component such as a magnetic disk such as a hard disk, an optical disk such as a CD, a magneto-optical disk such as an MO and a semiconductor memory such as a USB memory. The memory 121C and the external memory 123 may be embodied by a non-transitory computer readable recording medium. Hereafter, the memory 121C and the external memory 123 may be collectively or individually referred to as a “recording medium”. Thus, in the present specification, the term “recording medium” may refer to the memory 121C alone, may refer to the external memory 123 alone, and may refer to both of the memory 121C and the external memory 123. Instead of the external memory 123, a communication interface such as the Internet and a dedicated line may be used for providing the program to the computer.

The controller 120 is configured to be capable of controlling the abnormality determinator 121F configured to perform an abnormality determination on the substrates 100 based on the data respectively sent from the sensors 160 and 170 and a predetermined threshold value. Specifically, the controller 120 is configured to be capable of detecting the state of the substrate 100 (that is, each substrate 100 supported by the boat 32) by using the sensor 160 and the sensor 170 by controlling an elevating and lowering operation of the elevation driver 58, and is configured to be capable of controlling the abnormality determinator 121F to perform the abnormality determination on each substrate 100 based on the data detected by the sensors 160 and 170.

The controller 120 controls the elevating and lowering operation of the elevation driver 58 to elevate and lower the boat 32 such that a detection position by the sensor 160 (i.e., where the detection is made by the sensor 160) is located at a first measurement position of the boat 32 where the state of the substrate 100 accommodated in the upper region 140 can be checked. Specifically, when performing an abnormality determination process for the substrate 100 supported by the boat 32, first, the controller 120 moves the boat 32 to a first elevation position where the detection position by the sensor 160 is located at the first measurement position. According to the present embodiments, the first elevation position refers to an elevation position of the boat 32 with respect to the load lock chamber 14 shown in FIG. 4A. At the first elevation position, the detection position by the sensor 160 is located between a seventh slot and an eighth slot of the boat 32. That is, the first measurement position is located between the seventh slot and the eighth slot of the boat 32. Further, in FIGS. 4A to 4C, each of the optical path of the sensor 160 and the optical path of the sensor 170 is shown by a dashed-dotted line. Slots of the boat 32 respectively refer to portions of the boat 32 in which the substrates 100 supported by the support structure 40 are accommodated. When the substrate 100 is placed on a slot, the light from a sensor such as the sensor 160 and the sensor 170 hits the substrate 100.

Subsequently, the controller 120 controls the elevating and lowering operation of the elevation driver 58 to lower the boat 32 such that the detection position by the sensor 160 is changed from the first measurement position to a second measurement position of the boat 32 where the substrate 100 supported at an upper end of the boat 32 can be measured. Hereinafter, the substrate 100 supported at the upper end of the boat 32 may also be simply referred to as an “uppermost substrate 100”. Specifically, the controller 120 lowers the boat 32 from the first elevation position to a position where the sensor 160 can detect the uppermost substrate 100. A second elevation position of the boat 32 is an elevation position of the boat 32 at which the sensor 160 can detect the uppermost substrate 100 of the boat 32. According to the present embodiments, the second elevation position refers to the elevation position of the boat 32 with respect to the load lock chamber 14 shown in FIG. 4B. At the second elevation position, the detection position by the sensor 160 is located above a surface of the substrate 100 supported by a twenty fifth slot of the boat 32. That is, the second measurement position is above the surface of the substrate 100 supported by the twenty fifth slot in the boat 32.

The abnormality determinator 121F of the controller 120 is configured to perform the abnormality determination on the substrates 100 supported by the boat 32 located within a range from the first measurement position to the second measurement position based on the data sent from the sensor 160. The abnormality determination on the substrates 100 by the abnormality determinator 121F will be described later.

Further, the controller 120 controls the elevating and lowering operation of the elevation driver 58 to elevate or lower the boat 32 such that a detection position by the sensor 170 is located at a third measurement position of the boat 32 where the state of the substrate 100 accommodated in the lower region 150 can be checked and where the substrate 100 supported at a lower end of the boat 32 can be measured. Hereinafter, the substrate 100 supported at the lower end of the boat 32 may also be simply referred to as a “lowermost substrate 100”. A third elevation position of the boat 32 is an elevation position of the boat 32 at which the sensor 170 can detect the substrate 100 accommodated in the lower region 150. According to the present embodiments, the third elevation position refers to the elevation position of the boat 32 with respect to the load lock chamber 14 shown in FIG. 4B. While the boat 32 is placed at the third elevation position, a position lower than the back surface of the substrate 100 supported in the first slot in the boat 32 is used as the detection position by the sensor 170. That is, the third measurement position is located below the back surface of the substrate 100 supported in the first slot in the boat 32. For example, the present embodiments will be described by way of an example in which the second elevation position and the third elevation position of the boat 32 are the same position. However, the present embodiments are not limited thereto. For example, the second elevation position may be higher than the third elevation position. In such a case, the boat 32 is moved from the second measurement position to the third measurement position simply by lowering the boat 32.

Subsequently, the controller 120 controls the elevating and lowering operation of the elevation driver 58 to lower the boat 32 such that the detection position by the sensor 170 is located at a fourth measurement position of the boat 32, which is a position above the third measurement position. A fourth elevation position of the boat 32 is an elevation position of the boat 32 at which the sensor 170 can detect the substrate 100 supported above the third measurement position of the boat 32. The fourth elevation position of the boat 32 is located below the third elevation position. Further, according to the present embodiments, the fourth elevation position refers to an elevation position of the boat 32 with respect to the load lock chamber 14 shown in FIG. 4C. At the fourth elevation position, the detection position by the sensor 170 is located between the seventh slot and the eighth slot of the boat 32. That is, the fourth measurement position is located between the seventh slot and the eighth slot of the boat 32.

The abnormality determinator 121F of the controller 120 is configured to perform the abnormality determination on the substrates 100 supported by the boat 32 located within a range from the third measurement position to the fourth measurement position based on the data sent from the sensor 170. The abnormality determination on the substrates 100 by the abnormality determinator 121F will be described later.

In addition, according to the present embodiments, when the boat 32 is lowered from the first elevation position to the fourth elevation position, first, between the first elevation position and the second elevation position (third elevation position), the sensor 160 sequentially detects the substrates 100 supported in the eighth slot to the twenty fifth slot, respectively, in this order from the eighth slot. Then, between the third elevation position and the fourth elevation position, the sensor 170 sequentially detects the substrates 100 supported in the first slot to the seventh slot, respectively, in this order from the first slot. According to the present embodiments, the third elevation position of the boat 32 may be lower than or above the second elevation position. When the third elevation position is above the second elevation position, a detection of each slot by the sensor 160 and a detection of each slot by the sensor 170 may be performed in an alternate or overlapping manner. When the detection by the sensor 160 and the detection by the sensor 170 is performed in the overlapping manner, it is preferable that a detection result by the sensor 160 (that is, the data acquired by the detection by the sensor 160) is first used to perform the abnormality determination, and then a detection result by the sensor 170 (that is, the data acquired by the detection by the sensor 170) is used to perform the abnormality determination. For example, when the detection of each slot by the sensor 160 and the detection of each slot by the sensor 170 are performed in the alternate or overlapping manner, it is possible to shorten a time for determining whether each of the substrates 100 supported by the boat 32 is abnormal.

Further, as shown in FIGS. 4A, 4B and 4C, according to the present embodiments, the sensor 170 is configured to be capable of checking the state of the substrate 100 located at a support position (also referred to as a “slot position”) where the state of the substrate 100 cannot be checked by the sensor 160 even when the sensor 160 is operating within the range (also referred to as an “operation range” of the elevation driver 58) in which the boat 32 can be elevated or lowered by the elevation driver 58. That is, according to the present embodiments, the sensor 160 and the sensor 170 are respectively arranged such that states of the substrates 100 supported by the boat 32 can be checked without duplication. Therefore, by controlling an elevating and lowering operation of the boat 32, the controller 120 is configured to be capable of checking the states of the substrates 100 supported by the boat 32 without duplication.

The controller 120 is configured to be capable of checking the state of the substrate 100 in the lower region 150 after checking the state of the substrate 100 in the upper region 140. Specifically, the controller 120 continuously lowers the boat 32 from the first elevation position of the boat 32 shown in FIG. 4A to the fourth elevation position of the boat 32 shown in FIG. 4C. That is, after the sensor 160 detects each substrate 100 from the first measurement position to the second measurement position of the boat 32, the sensor 170 continuously detects each substrate 100 from the third measurement position to the fourth measurement position of the boat 32. Thereby, it is possible to efficiently check the state of the substrate 100 accommodated in each slot of the boat 32.

When it is determined that there is an abnormality in the substrate 100 based on a determination result from the abnormality determinator 121F, the controller 120 notifies the manipulator 122 of the abnormality in the substrate 100. Specifically, a message notifying the abnormality of the substrate 100 is displayed on the display 124 via the manipulator 122. However, the present embodiments are not limited thereto. For example, the abnormality in the substrate 100 may be displayed on an external display via a communication line.

Further, the abnormality determinator 121F of the controller 120 is configured to be capable of confirming the presence or absence of the substrate 100 based on a change in an amount of the light from the sensor such as the sensor 160 and the sensor 170 according to a movement of the substrate 100 due to the elevating and lowering operation of the elevation driver 58. Hereinafter, the abnormality determination process for the substrate 100 by the abnormality determinator 121F will be described.

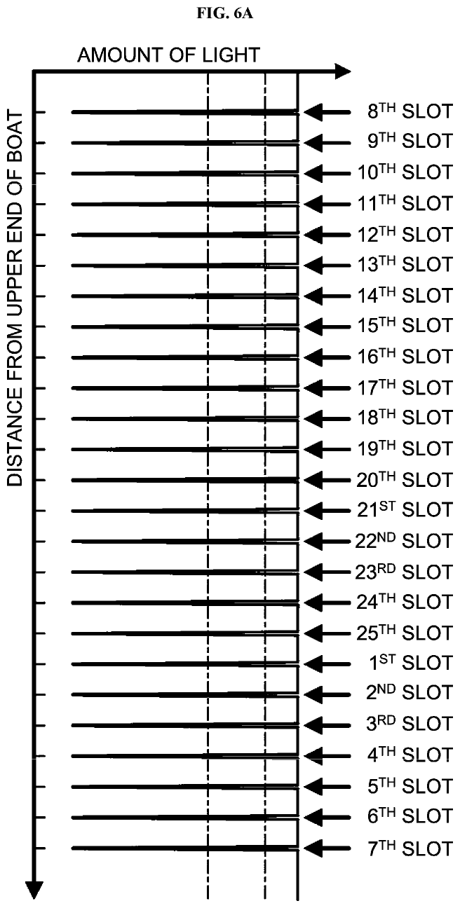

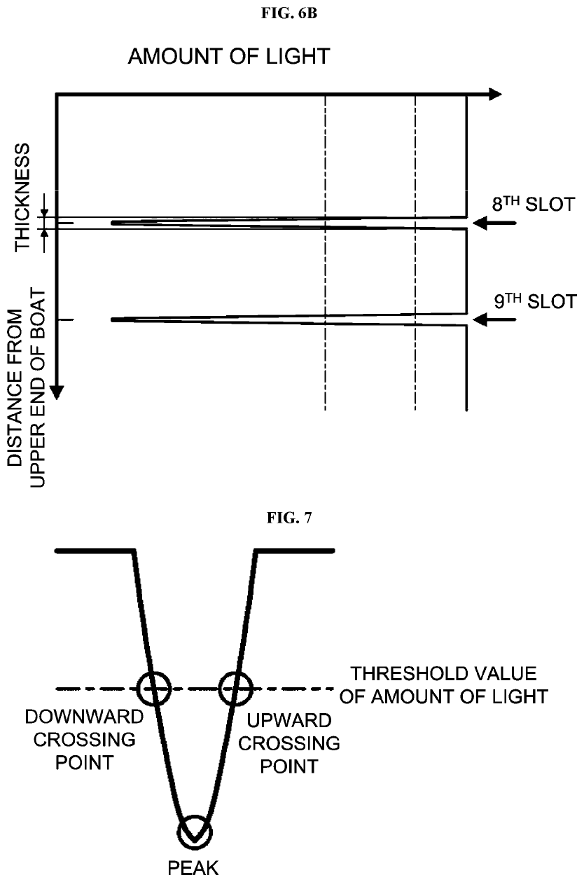

FIG. 6A shows an example in which the abnormality determination process is performed by using the sensor 160 and the sensor 170 in a state where the substrates 100 are accommodated in the entirety of the slots of the boat 32. In the example shown in FIG. 6A, the abnormality determinator 121F determines that the entirety of the substrates 100 are in a normal state. FIG. 6B is a diagram schematically illustrating an enlarged view of a part of FIG. 6A. When the light from a transmitter (light emitter) of the sensor such as the sensor 160 and the sensor 170 hits the substrate 100, the amount of the light received by a receiver (light receiver) of the sensor decreases. Specifically, when the light passes through an end surface (outer peripheral end surface) of the substrate 100 in a thickness direction of the substrate 100, the amount of the light decreases the most at the end surface of the substrate 100. In a waveform shown in FIG. 6B, a peak of the waveform corresponds to a center of the thickness of the end surface of the substrate 100, and roots on both sides of the waveform correspond to both edges of the end surface of the substrate 100. Therefore, it is possible to calculate a thickness of the substrate 100 from a distance between the roots on both sides of the waveform.

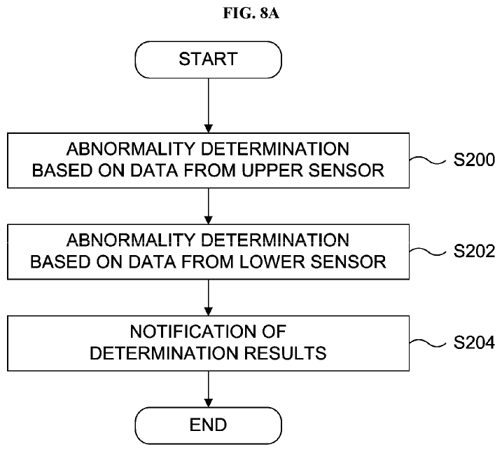

In addition, FIG. 7 shows a part of the waveform shown in FIG. 6A and FIG. 6B. As shown in FIG. 7, the abnormality determinator 121F determines the peak of the waveform, an upward crossing point of the waveform and a downward crossing point of the waveform with respect to a predetermined threshold value of the amount of the light for the waveform. Waveform information such as the peak, the upward crossing point and the downward crossing point may be stored in the RAM 121B or the memory 121C in association with the slot in which each substrate 100 is accommodated. When the peak, the upward crossing point and the downward crossing point of the waveform are apart from a predetermined peak, a predetermined upward crossing point and a predetermined downward crossing point of the waveform by more than a predetermined threshold, the abnormality determinator 121F determines that the abnormality has occurred in the substrate 100. The determination result by the abnormality determinator 121F is sent to the manipulator 122 via the controller 120.

### Method of Manufacturing Semiconductor Device

Subsequently, a method of manufacturing the semiconductor device by using the substrate processing apparatus 10, that is, process sequences of the substrate processing of processing the substrate 100 will be described. Further, in the following description, as described above, operations of components constituting the substrate processing apparatus 10 are controlled by the controller 120.

First, the substrates 100 stored in the pods 27-1 to 27-3 are transferred into the atmospheric transfer chamber 12 by the atmospheric robot 30.

Subsequently, after setting (adjusting) the inner pressure of the load lock chamber 14 to the atmospheric pressure, the gate valve 104 is opened. Specifically, the gas supply valve 43 of the gas supply pipe 42 is opened to supply the inert gas into the load lock chamber 14. After setting the inner pressure of the load lock chamber 14 to the atmospheric pressure in a manner described above, the gate valve 104 is opened.

Subsequently, the substrate 100 is transferred (loaded) into the load lock chamber 14. Specifically, the substrate 100 loaded into the atmospheric transfer chamber 12 is transferred into the load lock chamber 14 by the atmospheric robot 30, and is placed on the support structure 40 of the boat 32. Thereby, the substrate 100 is supported by the boat 32.

Subsequently, after the gate valve 104 is closed, the inner pressure of the load lock chamber 14 is set to the vacuum pressure. Specifically, after a predetermined number of the substrates 100 are supported by the boat 32, the valve 45 of the exhaust pipe 44 is opened so as to exhaust the inside of the load lock chamber 14 by the vacuum pump 46. Thereby, it is possible to set the inner pressure of the load lock chamber 14 to the vacuum pressure. Further, when setting the inner pressure of the load lock chamber 14 to the vacuum pressure, an inner pressure of the transfer chamber 16 and an inner pressure of the process chamber 18 are also set to the vacuum pressure.

Further, before the substrate 100 is transferred from the load lock chamber 14 to the process chamber 18, the abnormality determination process for the substrate 100, which is an example of a substrate checking method of the present embodiments, is performed.

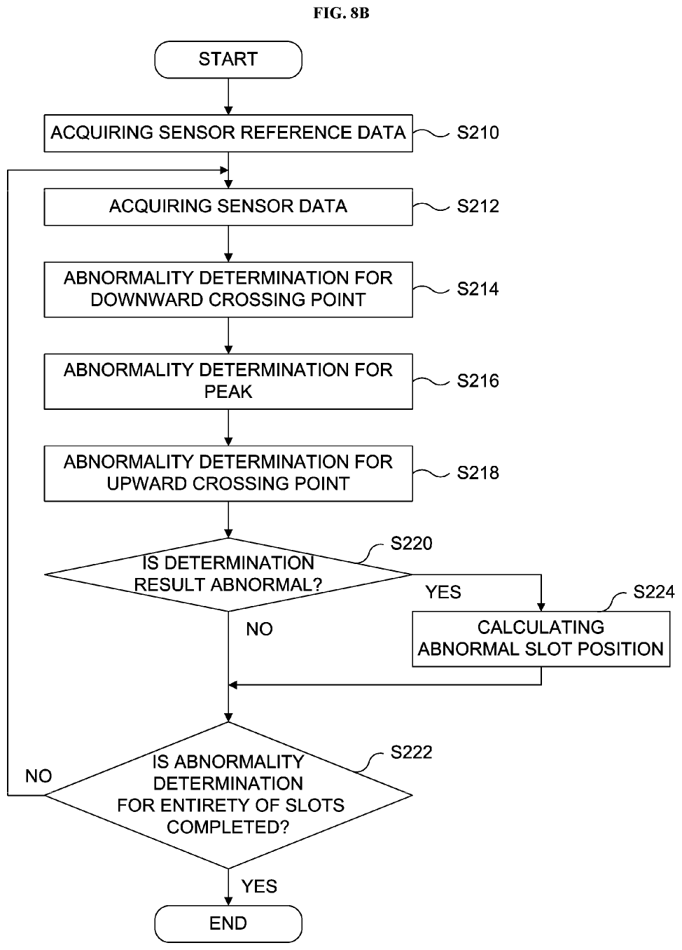

The abnormality determination process for the substrate 100 may be roughly divided into an abnormality determination process for the entirety of the substrates 100 shown in FIG. 8A and an abnormality determination process for each substrate 100 shown in FIG. 8B.

First, the abnormality determination process shown in FIG. 8A will be described. First, as shown in FIG. 8A, in a step S200, the controller 120 controls the abnormality determinator 121F to obtain the result of the abnormality determination for the eighth slot to the twenty fifth slot based on the data from the sensor 160 serving as an example of an upper sensor. Then, in a step S202, the controller 120 controls the abnormality determinator 121F to obtain the result of the abnormality determination for the first slot to the seventh slots based on the data from the sensor 170 serving as an example of a lower sensor. Then, the controller 120 notifies the manipulator 122 of the determination result in the step S200 and the step S202 (step S204). When the entirety of the substrates 100 are normal, the substrates 100 are transferred from the load lock chamber 14 to the process chamber 18.

Subsequently, the abnormality determination process shown in FIG. 8B will be described. First, when the abnormality determination process shown in FIG. 8B is performed, the controller 120 acquires reference data (predetermined threshold value) (also referred to as “sensor reference data”) of the sensor in a step S210. In the present embodiments, the reference data may be data obtained through experiments, may be data obtained when the substrate processing is normally completed, or may be data obtained by calculation.

Subsequently, the controller 120 moves the boat 32 to the first elevation position by elevating and lowering the elevation driver 58. In other words, the boat 32 is elevated and lowered such that the detection position by the sensor 160 is at the first measurement position of the boat 32. Thereafter, the controller 120 continuously lowers the boat 32 from the first elevation position to the fourth elevation position. When lowering the boat 32, sensor data is acquired for each substrate 100 in each slot by the sensor 160 and the sensor 170, and is stored in the memory 121C (step S212). In addition, the sensor data (waveform data) acquired in a manner described above is compared with the reference data. Specifically, first, in a step S214, the abnormality determination on the waveform acquired in a manner described above is performed for the downward crossing point of the waveform. Then, in a step S216, the abnormality determination on the waveform acquired in a manner described above is performed for the peak of the waveform. Finally, in a step S218, the abnormality determination on the waveform acquired in a manner described above is performed for the upward crossing point of the waveform. For example, the abnormality determination is processed by the abnormality determinator 121F. After determining the abnormality, a step S220 is performed.

In the step S220, the abnormality determinator 121F determines whether the substrate 100 is abnormal. Specifically, when any one of the downward crossing point, the peak and the upward crossing point of the waveform acquired in a manner described above deviates from the reference data, the abnormality determinator 121F determines that the substrate 100 is abnormal. When the abnormality determinator 121F determines that the substrate 100 is normal, a step S222 is performed. On the other hand, when the abnormality determinator 121F determines that the substrate 100 is abnormal, a step S224 is performed.

In the step S222, it is determined whether the abnormality determination on the substrate 100 for the entirety of the slots is completed. When the abnormality determination on the substrate 100 for the entirety of the slots has not been completed, the step S212 is performed again. When the abnormality determination on the substrate 100 for the entirety of the slots has been completed, the abnormality determination process for each substrate 100 is terminated.

In the step S224, an abnormal slot position is calculated. Specifically, a serial number of the slot in which the substrate 100 has been determined to be abnormal is stored in the memory 121C. Thereafter, the step S222 is performed.

As described above, the abnormality determination process for the substrate 100 is performed. When there is no abnormality in the substrates 100, the substrates 100 are transferred from the load lock chamber 14 to the process chamber 18 in a manner described below.

Subsequently, the substrate 100 is transferred from the load lock chamber 14 to the process chamber 18. Specifically, first, the gate valve 24 is opened. When opening the gate valve 24, the elevation driver 58 can elevate or lower the boat 32 such that the substrate 100 supported by the boat 32 is capable of being transferred (or taken out) by the vacuum robot 70. Further, the rotation driver 62 can rotate the boat 32 such that a substrate loading/unloading port of the boat 32 faces the transfer chamber 16.

The vacuum robot 70 extends the finger 78 of the arm structure 76 toward the boat 32 and places the substrate 100 on the finger 78. After retracting the finger 78, the vacuum robot 70 rotates the arm structure 76 such that the arm structure 76 faces the process chamber 18. Subsequently, the vacuum robot 70 extends the finger 78 such that the substrate 100 is loaded into the process chamber 18 through the communication structure 26 with the gate valve 28 opened.

In the process chamber 18, the substrate 100 placed on the finger 78 may be placed on the first mounting table 96 of the first process structure 80, or may be transferred to the mover 86 standing by on a side portion of the first process structure 80. After receiving the substrate 100, the mover 86 is rotated toward the second process structure 82 and places the substrate 100 on the second mounting table 92.

Then, in the process chamber 18, the substrate 100 is subjected to a predetermined process such as an ashing process. In the predetermined process, the temperature of the substrate 100 is elevated by being heated by the heater such as the first heater and the second heater, or by being heated by a reaction heat generated by performing the predetermined process.

Subsequently, the substrate 100 after the predetermined process is performed (that is, the processed substrate 100) is transferred from the process chamber 18 to the load lock chamber 14. A transfer of the substrate 100 from the process chamber 18 to the load lock chamber 14 is performed in an order reverse to that of loading the substrate 100 into the process chamber 18 described above. When transferring the substrate 100 from the process chamber 18 to the load lock chamber 14, the inside of the load lock chamber 14 is maintained in a vacuum state (that is, the inner pressure of the load lock chamber 14 is set to the vacuum pressure).

After the processed substrates 100 are loaded into the load lock chamber 14 and supported by the boat 32 in the multistage manner with the predetermined interval therebetween, the gate valve 24 is closed and the inner pressure of the load lock chamber 14 is set to the atmospheric pressure. Specifically, the gas supply valve 43 of the gas supply pipe 42 is opened to supply the inert gas into the load lock chamber 14. Thereby, the inner pressure of the load lock chamber 14 is set to the atmospheric pressure by supplying the inert gas. According to the present embodiments, the boat 32 and the substrates 100 supported by the boat 32 are cooled by the cooling structure (not shown) and the inert gas supplied into the load lock chamber 14. A cooling operation for the substrate 100 in the load lock chamber 14 is performed for a predetermined time. In addition, the inert gas supplied into the load lock chamber 14 may be cooled in advance in a location preceding the gas supply pipe 42 in order to promote the cooling operation.

Further, when the processed substrates 100 are completely loaded (placed) into the boat 32, the boat 32 is elevated or lowered to a position for cooling the processed substrates 100. According to the present embodiments, the cooling operation is performed while the boat 32 is elevated to the highest position such that the cooling by the cooling structure can be promoted.

Subsequently, the substrate 100 (which is cooled in a manner described above) is unloaded from the load lock chamber 14 to an atmospheric pressure region (for example, the atmospheric transfer chamber 12). Specifically, the substrate 100 is transferred from the load lock chamber 14 with the gate valve 104 open to the atmospheric transfer chamber 12 by using the atmospheric robot 30. Thereby, the transfer operation of the substrate 100 is completed. Further, by transferring the substrate 100 (which is cooled) to the atmospheric transfer chamber 12, a process of manufacturing the semiconductor device on the substrate 100 is completed.

Subsequently, actions (effects) according to the present embodiments will be described. According to the present embodiments, the abnormality determinator 121F determines the abnormality of the substrate 100 supported in each slot of the boat 32 based on the data sent from each of the sensor 160 and the sensor 170 and the predetermined threshold value (reference data). In the present embodiments, it is possible to detect the substrate 100 supported in each slot of the boat 32 by the sensor 160 disposed in the upper region 140 and the sensor 170 disposed in the lower region 150 of the load lock chamber 14. Thereby, it is possible to perform the abnormality determination process on the entirety of the substrates 100 transferred to the load lock chamber 14 without changing a structure of the load lock chamber 14, for example, without expanding (increasing) a height of the load lock chamber 14. In the present embodiments, the abnormality determination process for the substrate 100 includes determining whether the substrate 100 is placed in each slot of the boat 32 in a correct posture at a correct position. Further, even when the substrate 100 is warped, since the peak, the downward crossing point and the upward crossing point of the waveform obtained from the sensor data deviate from positions of the reference data, it is possible to determine that the substrate 100 is abnormal.

Further, according to the present embodiments, each of the sensors 160 and 170 is configured as a transmission type optical sensor. Therefore, as shown in FIG. 6B, it is possible to confirm the thickness of the substrate 100 by the amount of the light received by the light receiver of the optical sensor.

Further, according to the present embodiments, the sensors 160 and 170 are disposed on the outer peripheral wall 15C of the load lock chamber 14 such that the transmitters 162 and 172 and the receivers 164 and 174 are arranged at positions facing each other in the radial direction of substrate 100 supported by boat 32. Therefore, for example, as compared with a configuration in which the transmitters and the receivers are arranged at positions not facing each other in the radial direction of substrate, the substrate 100 can be reliably irradiated with the light from the sensor.

Further, according to the present embodiments, the sensors 160 and 170 are arranged so as to divide the boat 32 into the upper range corresponding to the upper region 140 and the lower range corresponding to the lower region 150, and to check the states of the substrates 100 supported by the boat 32. Thereby, it is possible to check the states of the substrates 100 in different slots by using the sensor 160 and the sensor 170. Therefore, it is possible to shorten the time for determining whether each of the substrates 100 supported by the boat 32 is abnormal.

Further, according to the present embodiments, the elevation driver 58 elevates and lowers the boat 32 such that the detection position by the sensor 160 is located at the first measurement position where the state of the substrate 100 accommodated in the upper region 140 can be checked. Then, the elevation driver 58 lowers the boat 32 such that the detection position by the sensor 160 changes from the first measurement position to the second measurement position of the boat 32. That is, the boat 32 is lowered from the first elevation position to the second elevation position. When lowering the boat 32, the abnormality determinator 121F performs the abnormality determination on the substrates 100 supported by the boat 32 located within the range from the first measurement position to the second measurement position based on the sensor data sent from the sensor 160. In a manner described above, by lowering the boat 32 from the first elevation position to the second elevation position, it is possible to continuously acquire the sensor data (light irradiation information), and as an example of the abnormality determination, it is also possible to easily confirm the presence or absence of the substrate 100 between each slot in the boat 32.

Further, according to the present embodiments, the elevation driver 58 elevates and lowers the boat 32 such that the detection position by the sensor 170 is located at the third measurement position where the state of the substrate 100 accommodated in the lower region 150 can be checked. Then, the elevation driver 58 lowers the boat 32 such that the detection position by the sensor 170 changes from the third measurement position to the fourth measurement position of the boat 32. That is, the boat 32 is lowered from the third elevation position to the fourth elevation position. When lowering the boat 32, the abnormality determinator 121F performs the abnormality determination on the substrates 100 supported by the boat 32 located within the range from the third measurement position to the fourth measurement position based on the sensor data sent from the sensor 170. In a manner described above, by lowering the boat 32 from the third measurement position to the fourth measurement position, it is possible to continuously acquire the sensor data (light irradiation information), and as an example of the abnormality determination, it is also possible to easily confirm the presence or absence of the substrate 100 between each slot in the boat 32.

Further, according to the present embodiments, the sensor 170 is configured to be capable of checking the state of the substrate 100 located at the support position (also referred to as the “slot position”) where the state of the substrate 100 cannot be checked by the sensor 160 even when the sensor 160 is operating within the range in which the boat 32 can be elevated or lowered by the elevation driver 58. Thereby, it is possible to check the states of the substrates 100 without changing the structure of the load lock chamber 14, and it is also possible to contribute to reducing a cost of an apparatus modification. Further, since a volume inside the load lock chamber 14 is not changed, an amount of the gas used in the load lock chamber 14 is also not changed. Thereby, it is possible to suppress the wasteful use of resources.

Further, according to the present embodiments, the controller 120 is configured to be capable of controlling a checking of the states of the substrates 100 supported by the boat 32 without duplication. By avoiding the duplication of the slots being measured by the sensors in a manner described above, it is possible to contribute to shortening the time for checking the state of the substrate 100 and it is also possible to contribute to suppressing a decrease in production efficiency.

Further, according to the present embodiments, the abnormality determinator 121F is configured to be capable of confirming the presence or absence of the substrate 100 based on the change in the amount of the light from each sensor according to the movement of the substrate 100 moves due to the elevating and lowering operation of the elevation driver 58. Since the presence or absence of the substrate 100 is confirmed by the change in the amount of the light in a manner described above, it is possible to suppress a complexity of an apparatus configuration.

Further, according to the present embodiments, when it is determined that there is the abnormality in the substrate 100 based on the determination result from the abnormality determinator 121F, the controller 120 notifies the manipulator 122 of the abnormality in the substrate 100. Therefore, an operating personnel can quickly grasp, via the manipulator 122, that there is the abnormality in the substrate 100. Further, since the abnormality is notified through the manipulator 122, it is possible for the operator to easily detect the abnormality. In addition, it is possible to perform a recovery work quickly after the abnormality occurs.

Further, according to the present embodiments, the controller 120 is configured to be capable of checking the state of the substrate 100 in the lower region 150 after checking the state of the substrate 100 in the upper region 140. Therefore, since the sensor data for the upper region 140 and the sensor data for the lower region 150 are not acquired redundantly (or overlappingly) by each sensor, it is possible to acquire the sensor data without performing a process to avoid a redundant acquisition of the sensor data. Thereby, it is possible to reduce a load on the controller 120.

For example, the embodiments described above is described by way of an example in which the state of the unprocessed substrate 100 is checked (that is, the abnormality determination process is performed before processing the substrate 100) in the load lock chamber 14. However, the technique of the present disclosure is not limited thereto. For example, the state of the processed substrate 100 may be checked (that is, the abnormality determination process may be performed after processing the substrate 100). Since the processed substrate 100 is likely to warp due to the heating, it is preferable to set a threshold value by considering a warp of the processed substrate 100.

For example, the embodiments described above is described by way of an example in which each of the sensors 160 and 170 includes the transmitter and the receiver. However, the technique of the present disclosure is not limited thereto. For example, each of the sensors 160 and 170 may be configured as a reflective type optical sensor. Even in such a case, it is possible to perform the abnormality determination on the substrate 100 from the reflected light. On the other hand, each of sensor 160 and sensor 170 may be configured as an ultrasonic sensor. In such a case, the ultrasonic sensor is provided inside the load lock chamber 14. The ultrasonic sensor can mainly detect the presence or absence of the substrate 100.

According to some embodiments of the present disclosure, it is possible to perform the abnormality determination on each substrate transferred to the load lock chamber with less dependence to the structure of the load lock chamber.

What is claimed is:

1. A substrate processing apparatus comprising:
a load lock chamber comprising:
an opening through which a substrate among a plurality of substrates is capable of being loaded into or unloaded from the load lock chamber; and
an upper region and a lower region with the opening interposed therebetween;
a substrate support provided in the load lock chamber and capable of supporting the plurality of substrates in a multistage manner at predetermined intervals;
an elevator capable of elevating and lowering the substrate support;
a plurality of sensors respectively provided on outer peripheral portions of the upper region and the lower region in the load lock chamber and configured to check a state of the substrate supported by the substrate support; and
a controller comprising an abnormality determinator and configured to be capable of controlling the abnormality determinator configured to perform an abnormality determination on the substrate based on data respectively sent from the plurality of sensors and a predetermined threshold value.

2. The substrate processing apparatus of claim 1, wherein each of the plurality of sensors comprises a transmission type optical sensor.

3. The substrate processing apparatus of claim 1, wherein each of the plurality of sensors comprises a transmitter and a receiver provided on the outer peripheral portions of the load lock chamber at mutually opposing positions in a radial direction of the substrate supported by the substrate support.

4. The substrate processing apparatus of claim 1, wherein each of the plurality of sensors is arranged so as to divide the substrate support into an upper range corresponding to the upper region and a lower range corresponding to the lower region, and to check the state of the substrate supported by the substrate support.

5. The substrate processing apparatus of claim 1, wherein the plurality of sensors comprise a first sensor located in the upper region, and
the elevator is configured to elevate and lower the substrate support such that a detection position by the first sensor is located at a first measurement position where the state of the substrate accommodated in the upper region is capable of being checked.

6. The substrate processing apparatus of claim 5, wherein the elevator is configured to lower the substrate support such that the detection position by the first sensor is changed from the first measurement position to a second measurement position where the substrate supported at an upper end of the substrate support is capable of being checked.

7. The substrate processing apparatus of claim 6, wherein the abnormality determinator is configured to perform the abnormality determination on the substrate supported by the substrate support located within a range from the first measurement position to the second measurement position based on the data sent from the first sensor.

8. The substrate processing apparatus of claim 1, wherein the plurality of sensors comprise a second sensor located in the lower region, and
the elevator is configured to elevate and lower the substrate support such that a detection position by the second sensor is located at a third measurement position where the state of the substrate accommodated in the lower region is capable of being checked and where the substrate supported at a lower end of the substrate support is capable of being measured.

9. The substrate processing apparatus of claim 8, wherein the elevator is configured to lower the substrate support such that the detection position by the second sensor is changed from the third measurement position to a fourth measurement position where the substrate supported above the third measurement position is capable of being measured.

10. The substrate processing apparatus of claim 9, wherein the abnormality determinator is configured to perform the abnormality determination on the substrate supported by the substrate support located within a range from the third measurement position to the fourth measurement position based on the data sent from the second sensor.

11. The substrate processing apparatus of claim 8, wherein the plurality of sensors comprise a first sensor located in the upper region, and
the second sensor is configured to be capable of checking the state of the substrate located at a support position where the state of the substrate is incapable of being checked by the first sensor even when the first sensor is operating within an operation range of the elevator.

12. The substrate processing apparatus of claim 1, wherein the controller is configured to be capable of controlling a checking of the state of the substrate supported by the substrate support without duplication.

13. The substrate processing apparatus of claim 1, wherein the abnormality determinator is configured to be capable of checking a presence or absence of the substrate based on a change in an amount of a light from each sensor according to a movement of the substrate due to an elevating and lowering operation of the elevator.

14. The substrate processing apparatus of claim 1, further comprising
a manipulator configured to be capable of presenting the state of the substrate,
wherein, when it is determined that there is an abnormality in the substrate based on a determination result from the abnormality determinator, the controller notifies the manipulator of the abnormality.

15. The substrate processing apparatus of claim 1, wherein the controller is configured to be capable of controlling a checking of the state of the substrate in the lower region after checking the state of the substrate in the upper region.

16. A substrate checking method comprising:
(a) supporting a plurality of substrates by a substrate support, wherein the substrate support is provided in a load lock chamber and is capable of supporting the plurality of substrates in a multistage manner at predetermined intervals substrate, and wherein the load lock chamber comprises an opening through which a substrate among the plurality of substrates is capable of being loaded into or unloaded from the load lock chamber and an upper region and a lower region with the opening interposed therebetween;
(b) elevating and lowering the substrate support;
(c) checking a state of the substrate supported by the substrate support by a plurality of sensors respectively provided on outer peripheral portions of the upper region and the lower region in the load lock chamber; and
(d) performing an abnormality determination on the substrate based on data respectively sent from the plurality of sensors and a predetermined threshold value.

17. A method of manufacturing a semiconductor device, comprising the substrate checking method of claim 16.

18. A non-transitory computer-readable recording medium storing a program that causes a substrate processing apparatus, by a computer, to perform:
(a) supporting a plurality of substrates by a substrate support, wherein the substrate support is provided in a load lock chamber and is capable of supporting the plurality of substrates in a multistage manner at predetermined intervals substrate, and wherein the load lock chamber comprises an opening through which a substrate among the plurality of substrates is capable of being loaded into or unloaded from the load lock chamber and an upper region and a lower region with the opening interposed therebetween;
(b) elevating and lowering the substrate support;
(c) checking a state of the substrate supported by the substrate support by a plurality of sensors respectively provided on outer peripheral portions of the upper region and the lower region in the load lock chamber; and
(d) performing an abnormality determination on the substrate based on data respectively sent from the plurality of sensors and a predetermined threshold value.
